(19) United States
(12) Patent Application Publication
(10) Pub. No.: US 2025/0132140 A1
(43) Pub. Date: Apr. 24, 2025

(54) METHOD OF MANUFACTURING SEMICONDUCTOR DEVICE, AND SUBSTRATE TREATMENT APPARATUS USING ETHER-CAT

(71) Applicant: ASM IP Holding B.V., Almere (NL)

(72) Inventor: Taku Omori, Tokyo (JP)

(21) Appl. No.: 18/999,398

(22) Filed: Dec. 23, 2024

Related U.S. Application Data
(62) Division of application No. 17/499,790, filed on Oct. 12, 2021, now Pat. No. 12,217,946.
(60) Provisional application No. 63/092,462, filed on Oct. 15, 2020.

(51) Int. Cl. H01J 37/32

(52) U.S. Cl. CPC H01J 37/3299; H01J 37/32082; H01J 2237/332

(57) ABSTRACT

Examples of a method of manufacturing a semiconductor device includes, in treatment of a substrate with the use of a plasma, acquiring an RF waveform from a reactor through an Ether CAT in real time, the RF waveform being a waveform relating to an electric power to be applied to an RF plate, and adjusting, by using the RF waveform, the electric power to be applied to the RF plate.

### CROSS-REFERENCE TO RELATED APPLICATIONS

This application is a divisional of, and claims priority to, U.S. patent application Ser. No. 17/499,790 filed Oct. 12, 2021, titled METHOD OF MANUFACTURING SEMICONDUCTOR DEVICE, AND SUBSTRATE TREATMENT APPARATUS USING ETHER-CAT, which claims priority to U.S. Provisional Patent Application Ser. No. 63/092,462 filed Oct. 15, 2020, titled METHOD OF MANUFACTURING SEMICONDUCTOR DEVICE, AND SUBSTRATE TREATMENT APPARATUS USING ETHER-CAT, the disclosures of which are hereby incorporated by reference in their entirety.

### FIELD

Examples are described which relate to a method of manufacturing a semiconductor device and a substrate treatment apparatus.

### BACKGROUND

In a conventional PEALD apparatus, a device called a PLC logger is used to monitor analog data relating to plasma emission. The data relating to the plasma emission can be said to be, in other words, data relating to RF. For example, data on intensity (voltage) of the plasma emission is captured only by the PLC logger.

This PLC logger captures analog data relating to the plasma emission, with a time resolution of 50 msec, for example, and then reports the monitored data to a Process Module Controller (PMC). The PMC saves the data in a log file. This system cannot report the analog data to be monitored to a Unique Platform Controller (UPC) that is a host controller, in real time, and results in collectively reporting the data for each process. Accordingly, there is no choice but to check the intensity of the plasma emission and the like later by a time stamp.

Because of this, the UPC cannot link analog data relating to the plasma emission to trend data in real time. In other words, no feedback can be given to the recipe control.

In addition, since data is captured and the necessity of the alarm is determined in the PLC logger, software for the PLC logger is needed in a conventional substrate treatment apparatus. Further, the PLC logger needs to be synchronized with a recipe execution unit of the PMC when the monitoring is executed, and accordingly, various restrictions occur when functions for monitoring are expanded. For example, in the case where it is desired to more finely monitor analog data relating to the plasma in recipe setting, the PLC logger cannot receive the content of the recipe as it is, and accordingly, it becomes necessary to add information for transmitting the additional setting to the PLC logger. Then, it becomes necessary to significantly change the software every time a new setting is added.

### SUMMARY

Some examples described herein may address the above-described problems. Some examples described herein may provide a method of manufacturing a semiconductor device and a substrate treatment apparatus that can monitor the intensity of the plasma emission in real time.

In some examples, a method of manufacturing a semiconductor device includes, in treatment of a substrate with the use of a plasma, acquiring an RF waveform from a reactor through an Ether CAT in real time, the RF waveform being a waveform relating to an electric power to be applied to an RF plate, and adjusting, by using the RF waveform, the electric power to be applied to the RF plate.

### BRIEF DESCRIPTION OF THE DRAWINGS

FIG. 1 illustrates a configuration example of a substrate treatment apparatus;

FIG. 2 illustrates a configuration example of processing circuitry;

FIG. 3 illustrates another configuration example of processing circuitry;

FIG. 4 illustrates an adjustment example of a process; and

FIG. 5 illustrates another adjustment example of a process.

### DETAILED DESCRIPTION

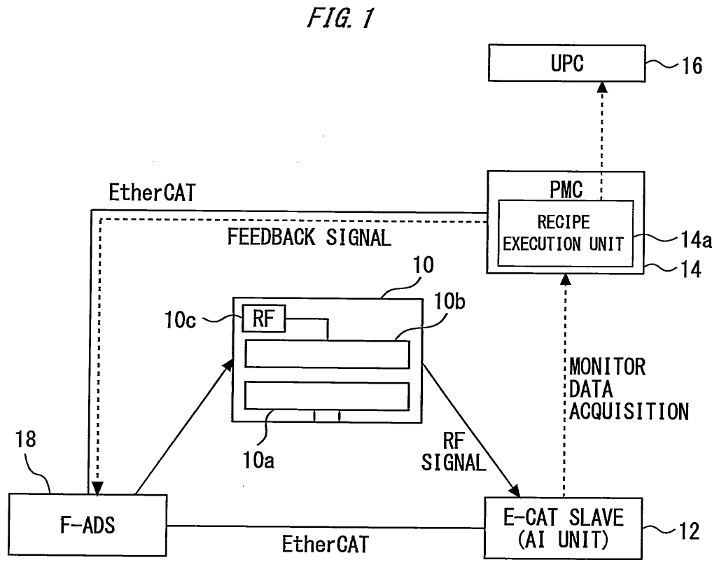

FIG. 1 illustrates a configuration example of a substrate treatment apparatus. The substrate treatment apparatus includes a reactor 10. The reactor 10 has a parallel plate structure including, for example, a susceptor 10a and an RF plate 10b. According to one example, the reactor 10 includes a gas supply system for providing a gas to a space between the susceptor 10a and the RF plate 10b. Furthermore, an RF unit 10c is provided that applies a high-frequency power to the RF plate 10b. According to one example, the RF unit 10c includes an RF generator and a matching box that connects the RF generator with the RF plate 10b.

Various types of reactors correspond to the reactor 10, which subject a substrate to plasma treatment by applying an electric power to the RF plate. For example, a reactor can apply two different high-frequency powers to the RF plate, or can supply a gas to be used for substrate treatment to a substrate through slits provided in the RF plate.

This reactor 10 is connected to the PMC 14 via an analog input unit (AI unit) 12 that is an Ethernet for Control Automation Technology (Ether CAT) slave. According to one example, the PMC 14 includes a recipe execution unit 14a. The recipe execution unit 14a includes processing circuitry, and the processing circuitry may be dedicated hardware or a CPU (also referred to as Central Processing Unit, central processor, processing unit, arithmetic unit, microprocessor, microcomputer, processor or DSP) that executes a program that is stored in a memory.

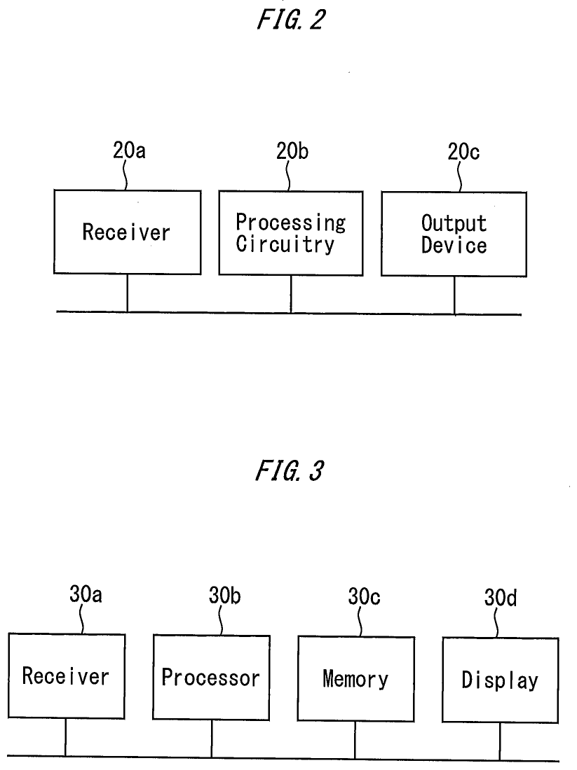

FIG. 2 is a block diagram of the recipe execution unit 14a in the case where the processing circuitry is dedicated hardware. The recipe execution unit includes a receiver 20a, a processing circuitry 20b, and an output device 20c. The receiver 20a receives analog data that has been measured in the substrate treatment that uses a recipe. The receiver 20a acquires, for example, an RF waveform that is a waveform relating to an electric power to be applied to the RF plate 10b, from the reactor 10 through the Ether CAT in real time. The RF waveform is a waveform of, for example, a traveling wave power, reflected wave power, a voltage value to be applied to the RF plate, or a value of an electric current flowing through the RF plate.

The processing circuitry 20b corresponds to, for example, a single circuit, a composite circuit, a programmed processor, a parallel programmed processor, an ASIC, an FPGA, or a combination thereof.

The respective functions of the recipe execution unit may be realized by the respective processing circuitries, or the respective functions may be collectively realized by the processing circuitry. According to one example, the processing circuitry 20b functions as a controller that adjusts an electric power to be applied to the RF plate 10b, with the use of the RF waveform that has been acquired by the receiver 20a.

The output device 20c issues a command to the RF unit 10c, basically based on the content of the recipe. According to one example, the command includes the RF power, the application time period of the RF power, the cycle of application of the RF power, and the number of times of application of the RF power. Furthermore, when the processing circuitry 20b has adjusted the applied power as described above, the output device 20c outputs a command for realizing the adjustment, to the RF unit 10c. According to one example, the output device 20c issues all instructions relating to RF, to the RF unit 10c via an interface referred to as an ADS board 18.

FIG. 3 is a block diagram illustrating a configuration example of the recipe execution unit 14a in the case where the processing circuitry is a CPU. In this case, the above series of processes is controlled by a program. A command to the RF unit 10c based on the recipe and an adjustment of the electric power to be applied to the RF plate 10b are automatically performed. When the processing circuitry 30b is the CPU as illustrated in FIG. 3, each function of the recipe execution unit 14a is realized by software, firmware, or a combination of software and firmware. The software or the firmware is described as a program, and is stored in a computer-readable storage medium 30c. Information for the above power adjustment is also stored in the storage medium 30c. According to one example, the program causes the computer to execute issuing a command to the RF unit 10c based on the recipe, and issuing a command reflecting the above power adjustment to the RF unit 10c.

In any of the configurations of FIGS. 2 and 3, the recipe execution unit 14a issues a command for executing a recipe and a command for adjusting the plasma treatment, to the RF unit 10c.

In FIG. 1, a UPC 16 is illustrated that is connected to the PMC 14. According to one example, the UPC 16 stores and monitors trend data of analog data created by the PMC 14. According to one example, the PMC 14 functions as an abnormality detection controller. The PMC 14 can include a calculation unit, a storage unit, an alarm determination unit and a sensor monitoring unit. According to one example, the PMC 14 issues an alarm when the RF waveform acquired in real time from the reactor 10 through the Ether CAT exceeds a determined range beforehand. According to one example, UPC 16 receives alarm signals from the PMC 14 and displays or records such alarm.

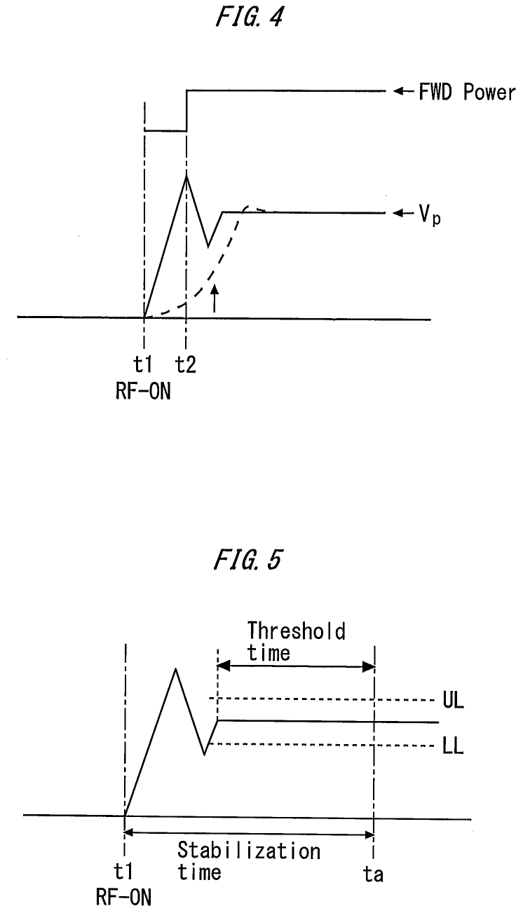

FIG. 4 is a voltage waveform diagram illustrating an example of adjustment of a voltage to be applied to the RF plate 10b. The waveform of the solid line is a target waveform. At the time t1, the RF power starts being applied to the RF plate 10b. The PMC 14 acquires an RF waveform of the electric power applied to the RF plate 10b, from the reactor 10 through the Ether CAT in real time. The voltage waveform that the PMC 14 has acquired is shown by a broken line. In the target waveform, such a spike occurs that the voltage rises sharply from the time t1 to the time t2, and after that, the voltage Vp is maintained. According to one example, the voltage Vp is a sufficient voltage for generating a plasma.

The PMC 14 acquires the RF waveform in real time, and by using the RF waveform, simultaneously determines whether or not the electric power to be applied to the RF plate 10b needs to be adjusted. In the example of FIG. 4, the PMC 14 compares the RF waveform from the time t1 at which the electric power has started being applied to the RF plate 10b, to the first time t2 determined beforehand, with a target waveform determined beforehand; and if the value of the RF waveform is smaller than the value of the target waveform, determines that the electric power to be applied to the RF plate needs to be adjusted. In the case of FIG. 4, a voltage in the waveform of the broken line between the time t1 and the time t2 is insufficient, as compared with that in the target waveform in the same period, and accordingly there is a possibility that the voltage does not reach the voltage Vp required to generate the plasma, and that the plasma is not generated. Then, the PMC 14 increases the electric power to be applied to the RF plate 10b so that the electric power to be applied to the RF plate after the first time t2 approaches the target. The amount of increase in the electric power to be applied to the RF plate can be controlled to such a level that the voltage reaches Vp. Thereby, in the example of FIG. 4, after the time t2, the voltage rises as is indicated by the broken line, and reaches the voltage Vp. In addition, it is also illustrated above the waveform that a forward power has been raised at the time t2.

According to another example, the PMC 14 compares the RF waveform with the target waveform determined beforehand, and if a power value of the RF waveform is greater than the power value of the target waveform, decreases the electric power to be applied to the RF plate so that the electric power to be applied to the RF plate after the first time t2 approaches the target.

According to further another example, when a difference between the RF waveform and the target waveform has exceeded a value determined beforehand, the PMC adjusts the electric power to be applied to the RF plate so as to decrease the difference. In this example, it has been determined at the time t2 whether or not the electric power needs to be adjusted, but it may be determined based on the data obtained before the time t2 whether or not the electric power needs to be adjusted, or may be determined based on the data obtained until after the time t2.

According to one example, the acquisition of the RF waveform and the adjustment of the electric power may be performed each time the electric power is applied to the RF plate in the PEALD process. Then, the substrate treatment apparatus can ensure the generation of the plasma each time the RF power is applied to the RF plate. In addition, the PMC 14 can acquire the RF waveform with a time resolution shorter than 50 msec.

In this way, by a protocol referred to as the Ether CAT being used for the management of the RF, it becomes possible for the PMC 14 to monitor the RF waveform in real time and adjust the electric power according to the monitoring result. According to such an example, it becomes possible to construct a monitoring system, due to only the application (module) in the PMC 14, specifically, only the recipe execution unit 14a. Because of this, the monitoring system can enhance the expandability of a monitoring function, and enables, for example, the power adjustment described above, or the power adjustment that will be described later. According to one example, the PMC 14 monitors the RF waveform in real time, and determines whether or not an alarm is necessary.

For example, when the RF waveform acquired in real time from the reactor 10 through the Ether CAT exceeds a range determined beforehand, the PMC 14 issues the alarm on a real time basis. The UPC 16 receives the alarm from the PMC 14 and displays or records such alarm so that user can learn about it on a real time basis.

Furthermore, the PMC 14 can associate the data of the RF waveform from the beginning to the end of the application of the electric power to the RF plate 10b with the trend data of the UPC.

FIG. 5 illustrates a state according to another example, in which the electric power to be applied to the RF plate is adjusted. The solid line shows an actually measured voltage waveform. In this adjustment, firstly, a stabilization time is obtained that is a time period between the time of RF-ON (start of application of RF power) and the time when the electric power applied to the RF plate becomes stable. The stabilization time ends at time Ta at which the time period during which the voltage applied to the RF plate is between the upper limit (UL) and the lower limit (LL) exceeds the threshold time. As for the RF waveform, the stabilization time ends when the time period during which the RF waveform transits between the upper threshold and the lower threshold reaches a threshold time determined beforehand.

By the time period being ensured during which a stable voltage is provided, it becomes possible to realize an intended plasma process. Then, the PMC 14 determines a necessary power application time period that is a time period during which the electric power is to be applied to the RF plate in succeeding times, from the stabilization time. For example, the PMC 14 can set the sum of the stabilization time and a time period determined beforehand, as the necessary power application time period. Then, the PMC 14 issues a command to the RF unit 10c so as to apply the electric power to the RF plate for the necessary power application time period. This allows the optimum RF application time period to be achieved. The PMC 14 can view the RF waveform in real time due to the Ether CAT, as described above; and accordingly can sequentially test a plurality of recipes and make the optimum setting. If a system with the PLC logger is used to carry out such processes, the log data is accumulated in the PLC logger, and the PLC logger frequently send the log data to the PMC as the PLC logger is unable to store large data. Further, PMC write the log data, as a log file, to predetermined locations in the UPC. Frequent writing operation made by the PMC imposes a heavy load on the UPC. The log file stored in the UPC can only be checked through the reference of the time stamp.

However, monitoring of the RF waveform in real time by the PMC makes it possible to convert the RF waveform into a form of a graph and adjust setting.

The above substrate treatment apparatus is provided as a PEALD apparatus, for example. The adjustment examples described with reference to FIGS. 4 and 5 are by way of example only, and it is also possible to adjust other parameters relating to the RF through real time monitoring of the RF waveform.

1. A substrate treatment apparatus comprising:
a reactor configured to subject a substrate to plasma treatment by applying an electric power to an RF plate; and
a process module controller (PMC) configured to acquire an RF waveform from the reactor through an ethernet for control automation technology (Ether CAT) in real time, the RF waveform being a waveform relating to an electric power to be applied to the RF plate, and adjust, by using the RF waveform, the electric power to be applied to the RF plate.

2. The substrate treatment apparatus according to claim 1, further comprising a unique platform controller (UPC) configured to issue an alarm when the RF waveform acquired from the reactor through the Ether CAT in real time exceeds a range determined beforehand.

3. The substrate treatment apparatus according to claim 2, wherein the UPC stores and monitors trend data of analog data created by the PMC.

4. The substrate treatment apparatus according to claim 1, comprising a susceptor opposite the RF plate.

5. The substrate treatment apparatus according to claim 1, wherein the RF plate comprises slits through which a gas is provided.

6. The substrate treatment apparatus according to claim 1, wherein the reactor is connected to the PMC via an analog input unit (AI unit).

7. The substrate treatment apparatus according to 7, wherein the AI unit is an Ether CAT slave.

8. The substrate treatment apparatus according to claim 1, wherein the PMC comprises a recipe execution unit that comprises processing circuitry, wherein the processing circuitry executes a program that is stored in a memory.

9. The substrate treatment apparatus according to claim 8, wherein the recipe execution unit comprises a receiver configured to receives analog data that has been measured in a substrate treatment that uses a recipe.

10. The substrate treatment apparatus according to claim 9, wherein the recipe execution unit comprises a processing circuitry, configured as a controller that adjusts the electric power to be applied to the RF plate.

11. The substrate treatment apparatus according to claim 9, comprising an RF unit, wherein the RF unit applies RF power to the RF plate.

12. The substrate treatment apparatus according to claim 11, wherein the RF unit comprises an RF generator and a matching box.

13. The substrate treatment apparatus according to claim 11, wherein the recipe execution unit comprises an output device configured to issue a command to the RF unit based on a content of the recipe.

14. The substrate treatment apparatus according to claim 13, wherein when the processing circuitry has adjusted an applied power, the output device issues a command for realizing an adjustment to the RF unit.

15. The substrate treatment apparatus according to claim 14, wherein the command is communicated to the RF unit based on the recipe and an adjustment of the electric power to be applied to the RF plate are automatically performed.

16. The substrate treatment apparatus according to claim 14, wherein the output device issues instructions to the RF unit 10 via an ADS board.

17. The substrate treatment apparatus according to 14, wherein the command includes the RF power, an application time period of the RF power, a cycle of application of the RF power, and a number of times of application of the RF power.

18. The substrate treatment apparatus according to claim 8, wherein the recipe execution unit is a central processing unit (CPU).

19. The substrate treatment apparatus according to claim 1, wherein an acquisition of the RF waveform and the adjustment of the electric power are performed each time electric power is applied to the RF plate in a process.

20. The substrate treatment apparatus according to claim 1, wherein the PMC compares the RF waveform with a target waveform determined beforehand, and if a power value of the RF waveform is greater than the power value of the target waveform, decreases the electric power to be applied to the RF plate.
